(19) United States
(12) Patent Application Publication
(10) Pub. No.: US 2025/0221262 A1
(43) Pub. Date: Jul. 3, 2025

(54) DISPLAY DEVICE

(71) Applicant: LG Display Co., Ltd., Seoul (KR)

(72) Inventor: JoonYoung HEO, Seoul (KR)

(73) Assignee: LG Display Co., Ltd., Seoul (KR)

(21) Appl. No.: 18/925,896

(22) Filed: Oct. 24, 2024

(30) Foreign Application Priority Data
Dec. 29, 2023 (KR) 10-2023-0196690

(51) Int. Cl. H10K 59/80; H10K 59/131

(52) U.S. Cl. CPC H10K 59/873; H10K 59/131

(57) ABSTRACT

A display device is disclosed. The display device according to the present disclosure includes a substrate, light emitting elements disposed over the substrate, an encapsulation layer covering the light emitting elements, and a protective layer disposed to surround side surfaces of the encapsulation layer. According to the present disclosure, it is possible to provide a display device with improved reliability against moisture and oxygen penetration.

### CROSS-REFERENCE TO RELATED APPLICATIONS

This application claims the priority of Korean Patent Application No. 10-2023-0196690 filed on Dec. 29, 2023, in the Korean Intellectual Property Office, the disclosure of which is incorporated herein by reference.

### BACKGROUND

### Technical Field

The present disclosure relates to a display device, and more particularly, for example, without limitation, to a stretchable display device with improved reliability against moisture and oxygen penetration.

### Discussion of the Related Art

As the society enters a full-scale information age, the field of displays that visually express electrical information signals has been developed rapidly. In response to this development, a variety of display devices with excellent performance such as thinness, weight reduction, and low power consumption are being developed. Examples of such display devices include a liquid crystal display (LCD) device, a field emission display (FED) device, an organic light emitting display (OLED) device, and the like.

The scope of application of the display device is becoming more diverse, including not only computer monitors and TVs but also personal portable devices. Research is being conducted on display devices that have a large active area but reduced volume and weight.

In addition, recently, display devices, which are manufactured by forming the display parts, lines, and the like on a flexible substrate formed of plastic or the like as a flexible material to be able to expand and contract in a specific direction and change into various shapes, are attracting attention as next-generation display devices.

The description provided in the description of the related art section should not be assumed to be prior art merely because it is mentioned in or associated with the description of the related art section. The description of the related art section may include information that describes one or more aspects of the subject technology, and the description in this section does not limit the invention.

### SUMMARY

The inventors have recognized that, in related art, a light emitting diode of a display device is easily damaged by moisture and oxygen.

Accordingly, embodiments of the present disclosure are directed to a display device that substantially obviates one or more of the problems due to limitations and disadvantages of the related art.

An aspect of the present disclosure is to provide a display device capable of protecting a light emitting diode from moisture and oxygen.

Another aspect of the present disclosure is to provide a display device capable of mitigating or minimizing damage to connection lines by protecting stretchable connection lines from moisture and oxygen.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises: a substrate; light emitting elements disposed over the substrate; an encapsulation layer covering the light emitting elements; and a protective layer disposed to surround side surfaces of the encapsulation layer.

Other detailed matters of the exemplary embodiments are included in the detailed description and the drawings.

According to the present disclosure, it is possible to protect the light emitting diode from being damaged due to the moisture and oxygen penetrating from the outside.

According to the present disclosure, it is possible to delay the moisture and oxygen from penetrating into the connection lines, etc.

According to the present disclosure, it is possible to improve the reliability of the light emitting diode or the connection lines.

The effects according to the present disclosure are not limited to the contents exemplified above, and further various effects are included in the present disclosure.

The effects of the present disclosure are not limited to the aforementioned effects, and other effects, which are not mentioned above, will be apparently understood to a person having ordinary skill in the art from the following description.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a display device according to an exemplary embodiment of the present disclosure;

FIG. 2 is an enlarged plan view of an active area of the display device according to the exemplary embodiment of the present disclosure;

FIG. 3 is a cross-sectional view taken along line III-III′ of FIG. 2;

FIG. 4 is an enlarged plan view of an active area of a display device according to another exemplary embodiment of the present disclosure;

FIG. 5 is a cross-sectional view taken along line V-V′ of FIG. 4;

FIG. 6 is an enlarged plan view of the active area of the display device according to still another exemplary embodiment of the present disclosure;

FIG. 7 is a cross-sectional view taken along line VII-VII′ of FIG. 6;

FIG. 8 is an enlarged plan view of the active area of the display device according to still another exemplary embodiment of the present disclosure; and

FIG. 9 is a cross-sectional view taken along line IX-IX′ of FIG. 8.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, areas, dimensions (e.g., length, width, height, thickness, radius, diameter, area, etc.), ratios, angles, numbers of elements, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “include,” “have,” “comprise,” “contain,” “constitute,” “make up of,” “formed of,” and “consist of” used herein are generally intended to allow other components to be added unless the terms are used with the term “only”. Any references to singular may include plural unless expressly stated otherwise.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Components are interpreted to include an ordinary error range even if not expressly stated.

When the position relation between two parts is described using the terms such as “on”, “above”, “over”, “below”, “under”, “beside”, “beneath”, “near”, “close to,” “adjacent to”, “on a side of”, “next”, one or more parts may be positioned between the two parts unless the terms are used with the term “immediately” or “directly”.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

In describing temporal relationship, terms such as “after,” “subsequent to,” “following,” “next,” “before,” and the like may include cases where any two events are not consecutive, unless the term such as “immediately” “just” or “directly” is explicitly used.

When an element or layer is disposed “on” another element or layer, another layer or another element may be interposed directly on the other element or therebetween.

Although the terms “first”, “second”, “A”, “B”, “(a)”, “(b)”, and the like are used for describing various components, these components are not confined by these terms. These terms are merely used for distinguishing one component from the other components. Therefore, a first component to be mentioned below may be a second component in a technical concept of the present disclosure.

In addition, terms, such as first, second, A, B, (a), (b), or the like may be used herein when describing components of the present disclosure. Each of these terminologies is not used to define an essence, order, or sequence of a corresponding component but used merely to distinguish the corresponding component from other components. In the case that it is described that a certain structural element or layer is “connected”, “coupled”, “adhered” or “joined” to another structural element or layer, it is typically interpreted that another structural element or layer may be “connected”, “coupled”, “adhered” or “joined” to the structural element or layer directly or indirectly.

It should be understood that the term “at least one” includes all combinations related with any one item. For example, “at least one among a first element, a second element and a third element” may include all combinations of two or more elements selected from the first, second and third elements as well as each element of the first, second and third elements.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, a display device according to exemplary embodiments of the present disclosure will be described in detail with reference to accompanying drawings.

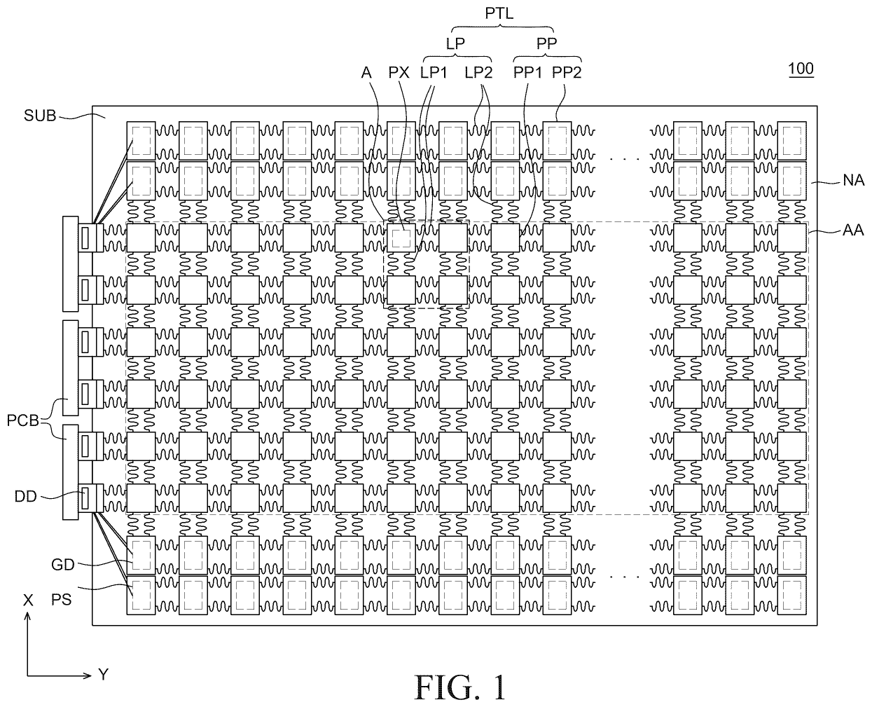

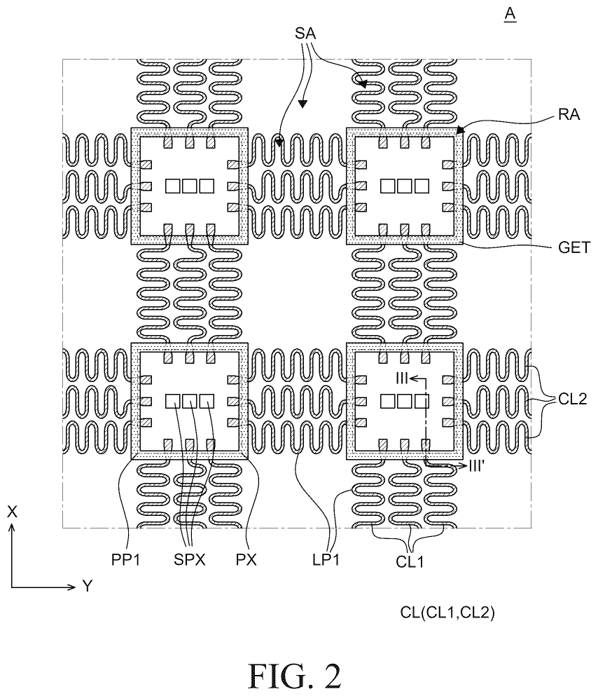

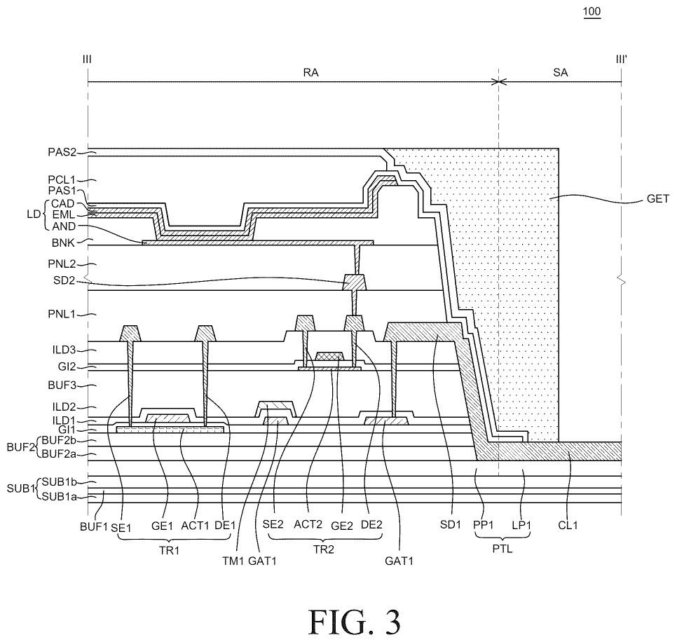

FIG. 1 is a plan view of a display device according to an exemplary embodiment of the present disclosure. FIG. 2 is an enlarged plan view of an active area of the display device according to the exemplary embodiment of the present disclosure. FIG. 3 is a cross-sectional view taken along line III-III′ of FIG. 2.

First, a display device 100 according to an exemplary embodiment of the present disclosure is a display device 100 capable of displaying an image even when being bent or stretched, and may also be referred to as a stretchable display device. The display device 100 may have higher flexibility and stretchability compared to conventional general display devices. Accordingly, not only may a user bend or stretch the display device 100, but a shape of the display device 100 may also be freely changed according to user's manipulation. For example, when the user holds and pulls an end of the display device 100, the display device 100 may be stretched in a direction in which the user pulls the display device 100. Alternatively, when a user disposes the display device 100 on an uneven outer surface, the display device 100 may be disposed to be curved along a shape of an outer surface. In addition, when a force applied by the user is removed, the display device 100 may be restored to its original form.

Referring to FIG. 1, FIG. 2 and FIG. 3 together, a substrate SUB1 is a substrate SUB1 for supporting and protecting various components of the display device 100. The substrate SUB1 may support a pattern layer PTL on which a pixel PX, a gate driver GD, and a power supply PS are formed. The substrate SUB1 may be a flexible substrate. Here, flexible characteristics may be interpreted to have the same meaning as bendable, unbreakable, rollable, and foldable characteristics.

The substrate SUB1 may be formed of a plastic material with flexibility. In some exemplary embodiments, the substrate SUB1 may be made of a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose (TAC), polyvinyl alcohol (PVA), and polystyrene (PS), and the present disclosure is not limited thereto.

When the substrate SUB1 is formed of the polyimide PI, moisture penetrates through the substrate SUB1 formed of the polyimide PI layer and penetrates to a plurality of transistors TR1 and TR2 and a plurality of light emitting diodes LD described later, thereby reducing the performance of the display device 100. Accordingly, the display device 100 according to the exemplary embodiment of the present disclosure may be configured as a double layer where the substrate SUB1 includes a first substrate SUB1a and a second substrate SUB1b. However, the number of layers of the substrate SUB1 is not limited thereto, and the substrate SUB1 may also include more than two layers.

In addition, a first buffer layer BUF1 may be disposed between the first substrate SUB1a and the second substrate SUB1b. For example, in the display device 100 according to the exemplary embodiment of the present disclosure, the second substrate SUB1b, the first buffer layer BUF1, and the first substrate SUB1a may be sequentially stacked from the lower portion. In this case, the first buffer layer BUF1 may be disposed between the first substrate SUB1a and the second substrate SUB1b to prevent moisture and oxygen, which may penetrate through the second substrate SUB1b disposed on the lower portion, from penetrating into the first substrate SUB1a. Accordingly, it is possible to improve the reliability of the display device 100.

The first buffer layer BUF1 may be composed of a single layer or a multi-layer formed of at least one of silicon nitride (SiNx), silicon oxide (SiOx), and silicon oxynitride (SiON). For example, the first buffer layer BUF1 may be formed by inorganic film in a single layer or in multiple layers, for example, the inorganic film in a single layer may be a silicon oxide (SiOx) film, a silicon nitride (SiNx) film, or a silicon oxynitride (SiON) film, and inorganic films in multiple layers may formed by alternately stacking at least two of one or more silicon oxide (SiOx) films, one or more silicon nitride (SiNx) films, and one or more silicon oxynitride (SiON) films, and one or more amorphous silicon (a-Si), but the present disclosure is not limited thereto. For example, the first buffer layer BUF1 may be formed of a silicon oxide film with excellent ductility, but is not limited thereto.

The substrate SUB1 may be capable of reversible expansion and contraction. Accordingly, the substrate SUB1 may also be referred to as a stretchable substrate SUB1, an elastic substrate SUB1, an elongation substrate SUB1, a soft substrate SUB1, a flexible substrate SUB1, etc, but is not limited thereto.

The substrate SUB1 includes an active area AA and a non-active area NA disposed in the vicinity of the active area AA, surrounding the active area AA, or around the active area AA. However, the active area AA and the non-active area NA are not limited to the substrate SUB1, but may be mentioned throughout the display device 100.

The active area AA is an area where images are displayed in the display device 100, and a plurality of pixels PX is disposed in the active area AA. In addition, each pixel PX may include a display element and various driving elements for driving the display element. Various driving elements may refer to at least one thin film transistor (TFT) and a capacitor, but are not limited thereto. For example, a number of transistors TFTs in the pixel circuit of the present disclosure may be two or more, and a number of capacitor may be one or more, for example, the pixel circuit of the present disclosure may be a 3T2C pixel circuit including three TFTs and two capacitors, a 5T1C pixel circuit including five TFTs and one capacitor, a 5T2C pixel circuit including five TFTs and two capacitors, a 7T2C pixel circuit including seven TFTs and two capacitors, or the like.

Active layers of transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Each of the plurality of pixels PX may be driven by being connected to various lines. For example, each of the plurality of pixels PX may be connected to various lines such as a gate line, a data line, a high potential voltage line, a low potential voltage line, a reference voltage line, and an initialization voltage line, but is not limited thereto.

The non-active area NA is an area where images are not displayed. The non-active area NA may be an area adjacent to the active area AA. In addition, the non-active area NA may be an area adjacent to the active area AA and surrounding the active area AA. However, the present disclosure is not limited thereto, and the non-active area NA corresponds to an area excluding the active area AA in the substrate SUB1, and may be modified and separated into various shapes. In the non-active area NA, components for driving the plurality of pixels PX disposed in the active area AA, for example, a gate driver GD and a power supply PS may be disposed. In addition, a plurality of pads connected to the data driver DD and a printed circuit board PCB may be disposed in the non-active area NA, and each pad may be connected to each of the plurality of pixels PX in the active area AA.

A pattern layer PTL is disposed on substrate SUB1. The pattern layer PTL includes a plurality of first plate patterns PP1 and a plurality of first line patterns LP1 disposed in the active area AA, and a plurality of second plate patterns PP2 and a plurality of second line patterns LP2 disposed in the non-active area NA.

A plurality of plate patterns PP is disposed in the active area AA and the non-active area NA. The plurality of plate patterns PP includes a plurality of first plate patterns PP1 and a plurality of second plate patterns PP2. The plurality of first plate patterns PP1 is disposed in the active area AA of the substrate SUB1, and the plurality of second plate patterns PP2 is disposed in the non-active area NA of the substrate SUB1. The plurality of pixels PX may be formed on the plurality of first plate patterns PP1, and the gate driver GD and the power supply PS may be formed on the plurality of second plate patterns PP2, but is not limited thereto.

The plurality of first plate patterns PP1 and the plurality of second plate patterns PP2 may be disposed in the form of islands spaced apart from each other. Each of the plurality of first plate patterns PP1 and the plurality of second plate patterns PP2 may be individually separated. Accordingly, the plurality of first plate patterns PP1 and the plurality of second plate patterns PP2 may be referred to as a first island pattern and a second island pattern or a first individual pattern and a second individual pattern, etc, but is not limited thereto.

Referring to FIG. 1, a size of each of the plurality of second plate patterns PP2 may be larger than a size of each of the plurality of first plate patterns PP1. One stage of the gate driver GD may be disposed in each of the plurality of second plate patterns PP2. Accordingly, since an area occupied by various circuit configurations constituting one stage of the gate driver GD is relatively larger than the area occupied by one pixel PX, the size of each of the plurality of second plate patterns PP2 may be larger than the size of each of the plurality of first plate patterns PP1. However, the present disclosure is not limited thereto, the size of each of the plurality of second plate patterns PP2 may also not be larger than the size of each of the plurality of first plate patterns PP1.

Meanwhile, FIG. 1 illustrates that the plurality of second plate patterns PP2 is disposed on both sides of the active area AA in the first direction X in the non-active area NA, for example, some portions of the plurality of second plate patterns PP2 are disposed in the non-active area NA which is at lower side of the active area AA in the first direction X, and other portions of the plurality of second plate patterns PP2 are disposed in the non-active area NA which is at upper side of the active area AA in the first direction X, but the present disclosure is exemplary, and the plurality of second plate patterns PP2 may be disposed in an arbitrary area of the non-active area NA for example, some portions of the plurality of second plate patterns PP2 are disposed in the non-active area NA which is at left side of the active area AA in the second direction Y, and other portions of the plurality of second plate patterns PP2 are disposed in the non-active area NA which is at right side of the active area AA in the second direction Y, but not limited thereto. In addition, the plurality of first plate patterns PP1 and the plurality of second plate patterns PP2 are illustrated in a square shape, but are not limited thereto, and the plurality of first plate patterns PP1 and the plurality of second plate patterns PP2 may be modified into various shapes.

Referring to FIGS. 1 and 2, the plurality of line patterns LP is disposed in the active area AA and the non-active area NA. The plurality of line patterns LP includes a plurality of first line patterns LP1 and a plurality of second line patterns LP2. The plurality of first line patterns LP1 is disposed in the active area AA. The plurality of first line patterns LP1 is patterns that connect first plate patterns PP1 adjacent to each other, and may also be referred to as internal connection patterns. That is, the plurality of first line patterns LP1 may be disposed between the plurality of first plate patterns PP1.

The plurality of second line patterns LP2 of the pattern layer PTL is disposed in the non-active area NA. The plurality of second line patterns LP2 may be referred to as patterns that connect the first plate pattern PP1 and the second plate pattern PP2 adjacent to each other or connect the plurality of second plate patterns PP2 adjacent to each other, and may also be referred to as external connection patterns. The plurality of second line patterns LP2 may be disposed between the first plate pattern PP1 and the second plate pattern PP2 adjacent to each other or between the plurality of second plate patterns PP2 adjacent to each other.

The plurality of first line patterns LP1 and the plurality of second line patterns LP2 have a curved shape. For example, the plurality of first line patterns LP1 and the plurality of second line patterns LP2 have a sinusoidal shape. However, the shapes of the plurality of first line patterns LP1 and the plurality of second line patterns LP2 are not limited thereto. For example, the plurality of first line patterns LP1 and the plurality of second line patterns LP2 may extend in a zigzag shape. Alternatively, the shapes of the plurality of first line patterns LP1 and the plurality of second line patterns LP2 may have various shapes, such as a shape in which a plurality of diamond-shaped substrates is connected and extended at vertices or a shape in which semi-circular and quarter-circular substrates are connected to each other. In addition, the shapes of the plurality of first line patterns LP1 and the shapes of the plurality of second line patterns LP2 may be same to each other, or may different from each other. For example, each of the plurality of first line patterns LP1 may have a sinusoidal shape, and each of the plurality of second line patterns LP2 may extend in a zigzag shape, but not limited thereto. In addition, the number and shape of the plurality of first line patterns LP1 and the plurality of second line patterns LP2 illustrated in FIG. 1 are exemplary, and the number and shapes of the plurality of first line patterns LP1 and the number and shapes of the plurality of second line patterns LP2 may variously change in various ways depending on the design.

Meanwhile, the plurality of first plate patterns PP1, the plurality of first line patterns LP1, the plurality of second plate patterns PP2, and the plurality of second line patterns LP2 are rigid patterns. For example, the plurality of first plate patterns PP1, the plurality of first line patterns LP1, the plurality of second plate patterns PP2, and the plurality of second line patterns LP2 have rigid properties compared to the substrate SUB1.

The plurality of first plate patterns PP1, the plurality of first line patterns LP1, the plurality of second plate patterns PP2, and the plurality of second line patterns LP2, which are the rigid patterns, may be formed of a plastic material with lower flexibility than the substrate SUB1. For example, the plurality of first plate patterns PP1, the plurality of first line patterns LP1, the plurality of second plate patterns PP2, and the plurality of second line patterns LP2 may be formed of at least one material of polyacrylate and polyacetate, but not limited thereto. In this case, when the plurality of first plate patterns PP1, the plurality of first line patterns LP1, the plurality of second plate patterns PP2, and the plurality of second line patterns LP2 are formed of the same material, the plurality of first plate patterns PP1, the plurality of first line patterns LP1, the plurality of second plate patterns PP2, and the plurality of second line patterns LP2 may be integrated. However, the plurality of first plate patterns PP1, the plurality of first line patterns LP1, the plurality of second plate patterns PP2, and the plurality of second line patterns LP2 may be formed of different materials, but are not limited thereto. For example, the plurality of first plate patterns PP1, the plurality of first line patterns LP1, the plurality of second plate patterns PP2, and the plurality of second line patterns LP2 may all be formed of different materials; alternatively, the plurality of first plate patterns PP1 and the plurality of first line patterns LP1 are formed of a same material, and the plurality of second plate patterns PP2 and the plurality of second line patterns LP2 are formed of a same material, but are not limited thereto.

Moduli of elasticity of the plurality of first plate patterns PP1, the plurality of first line patterns LP1, the plurality of second plate patterns PP2, and the plurality of second line patterns LP2 may be higher than that of the substrate SUB1. The modulus of elasticity is a parameter that represents a rate of deformation relative to the stress applied to the substrate SUB1. When the modulus of elasticity is relatively high, hardness may be relatively high. Accordingly, the plurality of first plate patterns PP1, the plurality of first line patterns LP1, the plurality of second plate patterns PP2, and the plurality of second line patterns LP2 may each be referred to as a plurality of first rigid patterns, a plurality of second rigid patterns, a plurality of third rigid patterns, and a plurality of fourth rigid patterns. The moduli of elasticity of the plurality of first plate patterns PP1, the plurality of first line patterns LP1, the plurality of second plate patterns PP2, and the plurality of second line patterns LP2 may be 1000 times higher than the modulus of elasticity of the substrate SUB1, for example, the moduli of elasticity of the plurality of first plate patterns PP1, the plurality of first line patterns LP1, the plurality of second plate patterns PP2, and the plurality of second line patterns LP2 may be 1500 times higher than the modulus of elasticity of the substrate SUB1, but is not limited thereto.

Meanwhile, in some exemplary embodiments, the substrate SUB1 may be defined as including a plurality of rigid areas RA and soft areas SA. The plurality of rigid areas RA may be an area that overlaps the pattern layer PTL in the substrate SUB1. The soft area SA may be an area that does not overlap the pattern layer PTL. Since the pattern layer PTL is disposed in the plurality of rigid areas RA, but the pattern layer PTL is not disposed in the soft area SA, the plurality of rigid areas RA may have more rigid characteristics than the soft area SA. In this case, the soft area SA and the plurality of rigid areas RA are not limited only to the substrate SUB1 but may be mentioned throughout the display device 100.

The gate driver GD may be mounted on the plurality of second plate patterns PP2. The gate driver GD may be formed on the plurality of second plate patterns PP2 by a gate in panel (GIP) method when manufacturing various components on the plurality of second plate patterns PP2. Accordingly, various circuit components constituting the gate driver GD, for example, transistors, capacitors, lines, etc., may be disposed on the plurality of second plate patterns PP2. The gate driver GD is formed over each of the plurality of second plate patterns PP2, and one stage, which is a circuit including transistors, capacitors, etc., may be disposed. However, the gate driver GD may be mounted by a chip on film (COF) method, but is not limited thereto.

A power supply PS is disposed on the plurality of second plate patterns PP2. The power supply PS may be formed on the second plate pattern PP2 adjacent to the gate driver GD. The power supply PS is a plurality of power blocks that is patterned when manufacturing various components on the second plate pattern PP2, and may be formed on the second plate pattern PP2. The power supply PS may be electrically connected to the gate driver GD of the non-active area NA and the plurality of pixels PX of the active area AA to supply a driving voltage. Specifically, the power supply PS may be electrically connected to the gate driver GD formed on the second plate pattern PP2 and a plurality of pixels PX formed on the first plate pattern PP1 through the second line pattern LP2 and the first line pattern LP1. For example, the power supply PS may supply a gate driving voltage and a clock signal to the gate driver GD. The power supply PS may supply a power supply voltage to each of the plurality of pixels PX.

The printed circuit board PCB is connected to an edge of the substrate SUB1. The printed circuit board PCB is a component that transmits signals and voltages for driving display elements from the control unit to the display elements. Accordingly, the printed circuit board PCB may also be referred to as a driving substrate. The printed circuit board PCB may be mounted with control units such as IC chips and circuit units. In addition, a memory, a processor, etc., may be mounted on the printed circuit board PCB. In addition, the printed circuit board PCB provided in the display device 100 may include a stretched area and a non-stretched area to secure stretchability. In addition, the IC chip, the circuit unit, the memory, the processor, etc., may be mounted in the non-stretched area, and lines electrically connected to the IC chip, the circuit unit, the memory, and the processor may be disposed in the stretched area.

The data driver DD is a component that supplies the data voltage to the plurality of pixels PX disposed in the active area AA. The data driver DD may be configured in the form of the IC chip, and therefore, may also be referred to as a data integrated circuit D-IC. In addition, the data driver DD may be mounted on the non-stretched area of the printed circuit board PCB. For example, the data driver DD may be mounted on the printed circuit board PCB in the form of a chip on board (COB). Although FIG. 1 illustrates that the data driver DD is mounted by the COB method, the data driver DD may be mounted by a method such as the chip on film (COF), chip on glass (COG), tape carrier package (TCP) methods, etc., but is not limited thereto.

In addition, FIG. 1 illustrates that one data driver DD is disposed corresponding to each of the plurality of columns formed by the plurality of first plate patterns PP1 disposed in the active area AA, but the present disclosure is not limited thereto. For example, one data driver DD may be disposed corresponding to a plurality of columns formed by the plurality of first plate patterns PP1, alternatively, two or more data driver DD may be disposed corresponding to a plurality of columns formed by the plurality of first plate patterns PP1. In addition, two or more data driver DD may be disposed at one side or two sides of the active area AA, but is not limited thereto.

Referring to FIGS. 1 and 2, the plurality of first plate patterns PP1 is spaced apart from each other and disposed on the active area AA of the substrate SUB1. For example, the plurality of first plate patterns PP1 may be disposed in a matrix form on the substrate SUB1 as illustrated in FIG. 1, but is not limited thereto. The plurality of first line patterns LP1 may connect the plurality of first plate patterns PP1 to each other. Some of the plurality of first line patterns LP1 connect the plurality of first plate patterns PP1 adjacent to each other in a first direction X, and others of the plurality of first line patterns LP1 may connect the plurality of first plate patterns PP1 adjacent to each other in a second direction Y, but not limited thereto.

Referring to FIGS. 2 and 3, pixels PX including a plurality of sub-pixels SPX, which is individual units that emit light, are disposed in the plurality of first plate patterns PP1. Each of the plurality of sub-pixels SPX may include a light emitting diode LD, which is a display element, and a pixel circuit (e.g., a driving transistor and a switching transistor) for driving the light emitting diode LD. The light emitting diode LD may be composed of an organic light emitting diode or an inorganic light emitting diode such as a micro light emitting diode (LED) or a quantum dot light emitting diode. In addition, the light emitting diode LD may be the light emitting diode LD formed of a composite of organic and inorganic materials. Furthermore, each of the plurality of pixels PX includes a single light emitting diode LD, or in another exemplary embodiment, each of the plurality of pixels PX includes a plurality of light emitting diodes LD, and the plurality of light emitting diode LDs may be connected to each other in series, parallel, or series-parallel. The display device 100 may display an image by driving the plurality of pixels PX in response to input image data.

Meanwhile, the plurality of sub pixels SPX is a minimum unit which configures the area and n sub pixels SPX form one pixel. Each of the plurality of sub pixels SPX may emit light having different wavelengths from each other. The plurality of sub pixels may include first to third sub pixels which emit different color light from each other. For example, the plurality of sub-pixels SPX may include a red sub-pixel SPX, a green sub-pixel SPX, and a blue sub-pixel SPX. According to the exemplary embodiment, at least some of the plurality of pixels PX may further include white sub-pixels SPX. Colors and configurations of the plurality of sub-pixels SPX may be changed in various ways as needed, but are not limited thereto.

For example, the plurality of sub pixels SPX may include red, green, and blue sub-pixels, in which the red, green, and blue sub-pixels may be disposed in a repeated manner.

Alternatively, the plurality of sub pixels SPX may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

A plurality of connection lines CL is disposed on the plurality of line patterns LP. The plurality of connection lines CL may be lines that electrically connect pads on the plurality of first plate patterns PP1 and the plurality of second plate patterns PP2 to each other. The plurality of connection lines CL is disposed between the plurality of first plate patterns PP1, between the plurality of second plate patterns PP2, and between the plurality of first plate patterns PP1 and the plurality of second plate patterns PP2. The plurality of connection lines CL may electrically connect pads on the plurality of first plate patterns PP1 to each other, electrically connect pads on the plurality of second plate patterns PP2 to each other, and electrically connect pads on the plurality of first plate patterns PP1 and the plurality of second plate patterns PP1 to each other, but not limited thereto.

The plurality of connection lines CL includes a first connection line CL1 and a second connection line CL2. The first connection line CL1 is a line extending between the plurality of first plate patterns PP1, between the plurality of second plate patterns PP2, and between the plurality of first plate patterns PP1 and the plurality of second plate patterns PP2 in a first direction X. The second connection line CL2 is a line extending between the plurality of first plate patterns PP1, between the plurality of second plate patterns PP2, and between the plurality of first plate patterns PP1 and the plurality of second plate patterns PP2 in a second direction Y. The plurality of connection lines CL may have a shape corresponding to the line pattern LP, for example, may have a curved shape. The plurality of connection lines CL may have a sinusoidal shape, but is not limited thereto. For example, the first connection line CL1 and the second connection line CL2 may have a same shape or have different shapes. For example, when any one of the plurality of first line patterns LP1 and the plurality of second line patterns LP2 has a sinusoidal shape, extends in a zigzag shape, has a shape in which a plurality of diamond-shaped substrates is connected and extended at vertices, or has a shape in which semi-circular and quarter-circular substrates are connected to each other, each of the first connection line CL1 and the second connection line CL2 has a shape corresponding to the plurality of first line patterns LP1 and/or the plurality of second line patterns LP2, for example, each of the first connection line CL1 and the second connection line CL2 has a sinusoidal shape, extends in a zigzag shape, has a shape in which a plurality of diamond-shaped substrates is connected and extended at vertices, or has a shape in which semi-circular and quarter-circular substrates are connected to each other.

The plurality of connection lines CL may have a stacked structure of metal materials such as copper (Cu), aluminum (Al), titanium (Ti), and molybdenum (Mo) or metal materials such as copper/molybdenum-titanium (Cu/Moti) and titanium/aluminum/titanium (Ti/Al/Ti), but is not limited thereto.

Meanwhile, in a general display device, various lines, such as a plurality of gate lines and a plurality of data lines, are disposed to extend in a straight line between the plurality of sub-pixels, and a plurality of sub-pixels is connected to one signal line. Accordingly, in the case of a general display device, various lines such as a gate line, a data line, a high potential voltage line, and a reference voltage line extend from one side to the other side of the display device without interruption on the substrate.

In contrast, in the case of the display device 100 according to the exemplary embodiment of the present disclosure, various lines, such as the straight gate line, data line, high potential voltage line, reference voltage line, and initialization voltage line that may be seen as used in a general display device, are disposed only on the plurality of first plate patterns PP1 and the plurality of second plate patterns PP2. That is, in the display device 100 according to the embodiment of the present disclosure, straight lines may be disposed only on the plurality of first plate patterns PP1 and the plurality of second plate patterns PP2.

In the display device 100 according to the exemplary embodiment of the present disclosure, pads on two first plate patterns PP1 adjacent to each other may be connected by the connection line CL. Accordingly, the connection line CL electrically connects the pads on the two adjacent first plate patterns PP1 to each other. Accordingly, the display device 100 according to the exemplary embodiment of the present disclosure may include the plurality of connection lines CL to electrically connect various lines, such as the gate line, the data line, the high potential voltage line, and the reference voltage line, between the plurality of first plate patterns PP1. For example, the gate line may be disposed on the plurality of first plate patterns PP1 disposed adjacent to each other in the first direction X, and the gate pads may be disposed at both ends of the gate line. In this case, each of the plurality of gate pads on the plurality of first plate patterns PP1 disposed adjacent to each other in the first direction X may be connected to each other by the first connection lines CL1 functioning as the gate lines. Accordingly, the gate line disposed on the plurality of first plate patterns PP1 and the first connection line CL1 disposed on the first line pattern LP1 may function as one gate line. In addition, among all the various lines that may be included in the display device 100, the line extending in the first direction X, for example, a light emitting signal line, a low potential voltage line, and a high potential voltage line may also be electrically connected by the first connection line CL1 as described above. For example, the light emitting signal line disposed on the plurality of first plate patterns PP1 and the first connection line CL1 disposed on the first line pattern LP1 may function as one light emitting signal line; for example, the low potential voltage line disposed on the plurality of first plate patterns PP1 and the first connection line CL1 disposed on the first line pattern LP1 may function as one low potential voltage line; for example, the high potential voltage line disposed on the plurality of first plate patterns PP1 and the first connection line CL1 disposed on the first line pattern LP1 may function as one high potential voltage line, however, the present disclosure is not limited thereto.

Some of the plurality of second connection lines CL2 may connect pads on the plurality of adjacent first plate patterns PP1 to each other in the second direction Y. Internal lines on the plurality of first plate patterns PP1 disposed in the second direction Y may be connected by the plurality of second connection lines CL2 functioning as the data lines, and one data voltage may be transmitted. For example, the data line disposed on the plurality of first plate patterns PP1 and the second connection line CL2 disposed on the first line pattern LP1 may function as one data line. In addition, the plurality of second connection lines CL2 may function as the high potential voltage line, the low potential voltage line, or the reference voltage line, but is not limited thereto. For example, the high potential voltage line disposed on the plurality of first plate patterns PP1 and the second connection line CL2 disposed on the first line pattern LP1 may function as one high potential voltage line; for example, the low potential voltage line disposed on the plurality of first plate patterns PP1 and the second connection line CL2 disposed on the first line pattern LP1 may function as one low potential voltage line; for example, the reference voltage line disposed on the plurality of first plate patterns PP1 and the second connection line CL2 disposed on the first line pattern LP1 may function as one reference voltage line, however, the present disclosure is not limited thereto.

Hereinafter, the cross-sectional structure of the active area AA will be described in detail with reference to FIG. 3.

Referring to FIG. 3, a second buffer layer BUF2 is disposed on the substrate SUB1 and the first plate pattern PP1. The second buffer layer BUF2 is formed on the plurality of first plate patterns PP1 to protect various components of the display device 100 from penetration of moisture and oxygen from the outside of the substrate SUB1 and the first plate pattern PP1. The second buffer layer BUF2 includes a multi-buffer layer BUF2a and an active buffer layer BUF2b. The second buffer layer BUF2 may be formed of an insulating material. For example, the second buffer layer BUF2 may be composed of a single layer or a multi-layer formed of at least one of silicon nitride (SiNx), silicon oxide (SiOx), and silicon oxynitride (SiON). For example, the second buffer layer BUF2 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. However, the second buffer layer BUF2 may be omitted depending on the structure or characteristics of the display device 100.

The first transistor TR1 is disposed on the second buffer layer BUF2. The first transistor TR1 includes a first active layer ACT1, a first gate electrode GE1, a first source electrode SE1, and a first drain electrode DE1.

The first active layer ACT1 is disposed on the second buffer layer BUF2. The first active layer ACT1 may include a source region connected to the first source electrode SE1, a drain region connected to the first drain electrode DE1, and a channel region between the source region and the drain region.

The first active layer ACT1 may include a polysilicon semiconductor layer formed through a low temperature polysilicon (LTPS) process, but the present disclosure is not limited thereto.

A first gate insulating layer GI1 is disposed on the first active layer ACT1. The first gate insulating layer GI1 is an insulating layer for insulating the first active layer ACT1 and the first gate electrode GE1. The first gate insulating layer GI1 may be composed of a single layer or a multi-layer of silicon nitride (SiNx) or silicon oxide (SiOx), but is not limited thereto. For example, the first gate insulating layer GI1 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The first gate electrode GE1 is disposed on the first gate insulating layer GI1. The first gate electrode GE1 is disposed to overlap the first active layer ACT1 with the first gate insulating layer GI1 interposed therebetween. The first gate electrode GE1 may be formed of one of various metal materials such as molybdenum (Mo), aluminum (Al), chromium (Cr), gold (Au), titanium (Ti), nickel (Ni), neodymium (Nd), and copper (Cu), or an alloy of two or more, or may be composed of a multi-layer thereof, but is not limited thereto.

A first interlayer insulating layer ILD1 is disposed on the first gate electrode GE1, and a second interlayer insulating layer ILD2 is disposed on the first interlayer insulating layer ILD1. The first interlayer insulating layer ILD1 and the second interlayer insulating layer ILD2 are disposed to cover the first gate electrode GE1, a first conductive layer GAT1, and a second conductive layer TM1. The first interlayer insulating layer ILD1 and the second interlayer insulating layer ILD2 may be composed of a single layer or a multi-layer of silicon nitride (SiNx) or silicon oxide (SiOx), but is not limited thereto. For example, each of the first interlayer insulating layer ILD1 and the second interlayer insulating layer ILD2 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The first conductive layer GAT1 is disposed between the first gate insulating layer GI1 and the first interlayer insulating layer ILD1. The first conductive layer GAT1 may constitute at least a portion of an emission control line that provides an emission control signal to the pixel PX, a scan line that provides a scan signal, and a power line that provides various power supply voltages. Here, when the first conductive layer GAT1 constitutes at least a portion of a power line that provides a power supply voltage, the first conductive layer GAT1 may be formed of a highly conductive material such as metal or conductive oxide. For example, the first conductive layer GAT1 may be composed of a single layer or multi-layer including aluminum (Al), copper (Cu), titanium (Ti), etc. In some exemplary embodiments, the first conductive layer GAT1 may be formed as a triple layer of titanium, aluminum, and titanium (Ti/Al/Ti) disposed sequentially. However, the composition of the first conductive layer GAT1 is not limited thereto, and the first conductive layer GAT1 may be composed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof. In addition, the first gate electrode GE1 disposed on the same layer as the first conductive layer GAT1 may be formed as the first conductive layer GAT1 that constitutes at least a portion of the emission control line or scan line among the first conductive layer GAT1.

A second conductive layer TM1 is disposed between the first interlayer insulating layer ILD1 and the second interlayer insulating layer ILD2. The second conductive layer TM1 includes molybdenum (Mo), copper (Cu), titanium (Ti), etc., and may be composed of a single layer or a multi-layer. The second conductive layer TM1 is disposed to overlap the first conductive layer GAT1 and may function as a kind of capacitor electrode.

A third buffer layer BUF3 is disposed on the second interlayer insulating layer ILD2. The third buffer layer BUF3 may be composed of a single layer or a multi-layer of silicon nitride (SiNx) or silicon oxide (SiOx), but is not limited thereto. For example, the third buffer layer BUF3 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The second transistor TR2 is disposed on the third buffer layer BUF3. The second transistor TR2 includes a second active layer ACT2, a second gate electrode GE2, a second source electrode SE2, and a second drain electrode DE2.

First, the second active layer ACT2 is disposed on the third buffer layer BUF3. The second active layer ACT2 may include a source region connected to the second source electrode SE2, a drain region connected to the second drain electrode DE2, and a channel region between the source region and the drain region. The second active layer ACT2 may include an oxide semiconductor layer.

A second gate insulating layer GI2 is disposed on the second active layer ACT2. The second gate insulating layer GI2 is an insulating layer for insulating the second active layer ACT2 and the second gate electrode GE2. The second gate insulating layer GI2 may be composed of a single layer or a multi-layer of silicon nitride (SiNx) or silicon oxide (SiOx), but is not limited thereto. For example, the second gate insulating layer GI2 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The second gate electrode GE2 is disposed on the second gate insulating layer GI2. The second gate electrode GE2 is disposed to overlap the second active layer ACT2 with the second gate insulating layer GI2 interposed therebetween. The second gate electrode GE2 may constitute at least a portion of the scan line. The second gate electrode GE2 may be formed of one of various metal materials such as molybdenum (Mo), aluminum (Al), chromium (Cr), gold (Au), titanium (Ti), nickel (Ni), neodymium (Nd), and copper (Cu), or an alloy of two or more, or may be composed of a multi-layer thereof, but is not limited thereto.

A third interlayer insulating layer ILD3 is disposed on the second gate electrode GE2. The third interlayer insulating layer ILD3 is disposed to cover the second gate electrode GE2. The third interlayer insulating layer ILD3 may be composed of a single layer or a multi-layer of silicon nitride (SiNx) or silicon oxide (SiOx), but is not limited thereto. For example, the third interlayer insulating layer ILD3 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The first source electrode SE1, the first drain electrode DE1, the second source electrode SE2, the second drain electrode DE2, and the third conductive layer SD1 are disposed on the third interlayer insulating layer ILD3.

The first source electrode SE1 and the first drain electrode DE1 may each be electrically connected to the first active layer ACT1 through contact holes. The contact holes are formed in the third interlayer insulating layer ILD3, the second gate insulating layer GI2, the third buffer layer BUF3, the second interlayer insulating layer ILD2, the first interlayer insulating layer ILD1, and the first gate insulating layer Gl1. The first source electrode SE1 and the first drain electrode DE1 may be formed of one of various metal materials such as molybdenum (Mo), aluminum (Al), chromium (Cr), gold (Au), titanium (Ti), nickel (Ni), neodymium (Nd), and copper (Cu), or an alloy of two or more, or may be composed of a multi-layer thereof, but is not limited thereto.

Each of the second source electrode SE2 and the second drain electrode DE2 may be electrically connected to the second active layer ACT2 through the contact holes formed in the third interlayer insulating layer ILD3 and the second gate insulating layer GI2. The second source electrode SE2 and the second drain electrode DE2 may be formed of one of various metal materials such as molybdenum (Mo), aluminum (Al), chromium (Cr), gold (Au), titanium (Ti), nickel (Ni), neodymium (Nd), and copper (Cu), or an alloy of two or more, or may be composed of a multi-layer thereof, but is not limited thereto.

The third conductive layer SD1 may extend to the side surfaces of the plurality of insulating layers disposed below the third conductive layer SD1 and be connected to the connection line CL disposed in the soft area SA. For example, the third conductive layer SD1 may extend from the top surface of the third interlayer insulating layer ILD3 to the side surface of the third interlayer insulating layer ILD3, the side surface of the second gate insulating layer GI2, the side surface of the third buffer layer BUF3, the side surface of the second interlayer insulating layer ILD2, the side surface of the first interlayer insulating layer ILD1, the side surface of the first gate insulating layer GI1, and the side surface of the second buffer layer BUF2. The extended third conductive layer SD1 may be connected to the connection line CL disposed on the first line pattern LP1. Accordingly, the third conductive layer SD1 may be a conductive layer that electrically connects the plurality of connection lines CL and various lines disposed on the first plate pattern PP1. The third conductive layer SD1 may be composed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof.

A first planarization layer PNL1 is disposed on the first source electrode SE1, the first drain electrode DE1, the second source electrode SE2, the second drain electrode DE2, and the third conductive layer SD1. The first planarization layer PNL1 is disposed to cover the first source electrode SE1, the first drain electrode DE1, the second source electrode SE2, the second drain electrode DE2, and the third conductive layer SD1. The first planarization layer PNL1 is an insulating layer for planarizing an upper portion of the first planarization layer PNL1 and protecting other components disposed below the first planarization layer PNL1. For example, the first planarization layer PNL1 may be formed of an organic material such as acryl resin, epoxy resin, phenolic resin, polyamide resin, and polyimide resin, but is not limited thereto.

A fourth conductive layer SD2 is disposed on the first planarization layer PNL1. The fourth conductive layer may be formed in the contact hole that penetrates through the first planarization layer PNL1 to expose the second drain electrode DE2. The fourth conductive layer SD2 may be a connection electrode that electrically connects the second transistor TR2 and the anode AND through the contact hole formed by penetrating through the first planarization layer PNL1. The fourth conductive layer SD2 may be formed of one of various metal materials such as molybdenum (Mo), aluminum (Al), chromium (Cr), gold (Au), titanium (Ti), nickel (Ni), neodymium (Nd), and copper (Cu), or an alloy of two or more, or may be composed of a multi-layer thereof, but is not limited thereto.

A second planarization layer PNL2 is disposed on the fourth conductive layer SD2. The second planarization layer PNL2 is disposed to cover the fourth conductive layer SD2. The second planarization layer PNL2 is an insulating layer for planarizing an upper portion of the second planarization layer PNL2 and protecting other components disposed below the second planarization layer PNL2. For example, the second planarization layer PNL2 may be formed of an organic material such as acryl resin, epoxy resin, phenolic resin, polyamide resin, and polyimide resin, but is not limited thereto.

The light emitting diode LD is disposed on the second planarization layer PNL2. The light emitting diode LD includes an anode electrode AND, an emission layer EML, and a cathode electrode CAD.

The anode electrode AND is disposed on the second planarization layer PNL2. The anode electrode AND may be formed of, for example, a transparent conductive material such as indium tin oxide (ITO) and indium zinc oxide (IZO), but is not limited thereto.

Meanwhile, when the display device 100 according to the exemplary embodiment of the present disclosure is a top emission type, the anode electrode AND may further include a reflective layer formed of a metal material with excellent reflection efficiency, for example, aluminum (Al) or silver (Ag) so that the light emitted from the emission layer EML is reflected by the anode electrode AND to be directed upward, that is, toward the cathode electrode CAD. Conversely, when the display device 100 is a bottom emission type, the anode may be formed only of a transparent conductive material.

A bank BNK covering a portion of the anode electrode AND is disposed on the second planarization layer PNL2. The bank BNK may be disposed to cover a portion of an edge of the anode electrode, and a portion of the anode electrode AND exposed from the bank BNK may correspond to the emission area. The bank BNK may be disposed at a boundary between the plurality of sub-pixels SPX to prevent light from each of the plurality of sub-pixels SPX from being mixed. In addition, the bank BNK may include at least one protrusion disposed adjacent to the outside of the rigid area RA. The bank BNK may include inorganic insulating materials such as silicon nitride (SiNx) and silicon oxide (SiOx) or organic insulating materials such as a benzocyclobutene (BCB)-based resin, an acryl-based resin, or polyimide, for example, the bank BNK may be formed of black resin but is not limited thereto.

The emission layer EML is disposed on the bank BNK and the anode electrode AND. The emission layer EML may be in contact with a portion of the anode electrode AND exposed from the bank BNK. In addition, at least a portion of the emission layer EML may overlap the top surface of the protrusion of the bank BNK. The emission layer EML may further include an organic material layer such as a hole injection layer, a hole transport layer, an electron transport layer, and an electron injection layer.

The cathode electrode CAD is disposed on the emission layer EML. The cathode electrode CAD supplies electrons to the emission layer EML, and therefore, may be formed of a conductive material with a low work function. The cathode electrode CAD may be formed of, for example, a transparent conductive material such as indium tin oxide (ITO) and indium zinc oxide (IZO) or a ytterbium (Yb) alloy, and may further include a metal doping layer, but is not limited thereto.

An encapsulation layer is disposed on the light emitting diode LD. The encapsulation layer has a structure in which an inorganic encapsulation layer and an organic encapsulation layer are alternately stacked, and may protect the light emitting diode LD to prevent moisture or oxygen from penetrating into the light emitting diode LD. For example, the encapsulation layer may have a multi-insulating film structure in which organic films and inorganic films are stacked alternately. The inorganic film can block permeation of moisture or oxygen. The organic film may planarize a surface of the inorganic film. When the organic film and the inorganic film are stacked in multiple layers, a movement path of moisture or oxygen may be longer than that of a single layer, thereby effectively blocking the permeation of moisture and oxygen affecting the light emitting layer EML. For example, the encapsulation layer includes a first inorganic encapsulation layer PAS1, a first organic encapsulation layer PCL1, and a second inorganic encapsulation layer PAS2 sequentially stacked.

The first inorganic encapsulation layer PAS1 and the second inorganic encapsulation layer PAS2 may serve to block the penetration of moisture or oxygen. The first inorganic encapsulation layer PAS1 and the second inorganic encapsulation layer PAS2 are formed of inorganic materials such as silicon nitride (SiNx), silicon oxide (SiOx), and aluminum oxide (AlOx), but are not limited thereto.

Each of the first inorganic encapsulation layer PAS1 and the second inorganic encapsulation layer PAS2 may entirely cover the top portions and side surfaces of the components disposed in the rigid area RA. For example, the first inorganic encapsulation layer PAS1 and the second inorganic encapsulation layer PAS2 may cover the upper portion of the light emitting diode LD disposed over the first plate pattern PP1. The first inorganic encapsulation layer PAS1 and the second inorganic encapsulation layer PAS2 are disposed between the light emitting diode LD and the first plate pattern PP1, and may cover the side surfaces of the plurality of insulating layers exposed to the outside and the third conductive layer SD1 that is disposed on the side surfaces of the plurality of insulating layers. The first inorganic encapsulation layer PAS1 and the second inorganic encapsulation layer PAS2 may extend beyond the rigid area RA to a portion of the soft area SA.

The first inorganic encapsulation layer PAS1 and the second inorganic encapsulation layer PAS2 may be in contact with each other in the soft area SA to seal the first organic encapsulation layer PCL1.

The first organic encapsulation layer PCL1 is disposed between the first inorganic encapsulation layer PAS1 and the second inorganic encapsulation layer PAS2. The first organic encapsulation layer PCL1 may be formed to be thicker than each of the first inorganic encapsulation layer PAS1 and the second inorganic encapsulation layer PAS2 to adsorb and block particles that may be generated during the manufacturing process of the display device 100. The first organic encapsulation layer PCL1 may fill cracks that may occur in the first inorganic encapsulation layer PAS1 and cover particles on the first inorganic encapsulation layer PAS1 to planarize the upper portion. The first organic encapsulation layer PCL1 may be formed of an organic material, such as an epoxy-based or acryl-based polymer, but is not limited thereto.

Meanwhile, the encapsulation layers are not limited to three layers, for example, n layers alternately stacked between inorganic encapsulation layer and organic encapsulation layer (where n is an integer greater than 3) may be included.

Next, a protective layer GET is disposed on the side surface of the encapsulation layer to surround the encapsulation layer. The protective layer GET is disposed to surround the side surface of the encapsulation layer, thereby protecting the light emitting diode LD to prevent moisture or oxygen from penetrating into the light emitting diode LD.

The protective layer GET may be disposed to overlap the bank BNK on the plurality of plate patterns PP. In addition, the top surface of the encapsulation layer and the top surface of the protective layer GET may be positioned on the same plane.

The protective layer GET may be disposed to completely cover the ends of the first inorganic encapsulation layer PAS1 and the second inorganic encapsulation layer PAS2 in the soft area SA. As a result, it is possible to prevent the first inorganic encapsulation layer PAS1 and the second inorganic encapsulation layer PAS2 from being separated.

The protective layer GET may be formed of a stretchable organic material. Organic materials may include at least one of, for example, isoprene rubber (IR), polyurethane (PUR), chloroprene rubber (CR), acrylic rubber (ACM), epichlorohydrin rubber (ECO), and polydimethylsiloxane (PDMS), but is not limited thereto.

In addition, the protective layer GET may include moisture-absorbing materials. The moisture-absorbing material may include at least one of, for example, barium oxide (BaO), calcium oxide (CaO), magnesium oxide (MgO), magnesium sulfate (MgSO₄), sodium oxide (Na₂O), sodium sulfate (Na₂SO₄), lithium sulfate (LiSO), calcium sulfate (CaSO₄), potassium oxide (K₂O), lithium oxide (Li₂O), gallium sulfate (GaS), calcium chloride (CaCl₂), magnesium chloride (MgCl₂), calcium bromide (CaBr₂), cerium bromide (CsBr), vanadium Bromide (VBr₅), and calcium nitrate (Ca(NO₃)₂), but is not limited thereto. Accordingly, the protective layer GET may absorb moisture that may penetrate from the outside, thereby protecting the light emitting diode LD from moisture.

The light emitting diode inside the display device is formed of organic materials and is vulnerable to moisture and oxygen, thereby shortening its lifespan and reducing reliability. Specifically, when the moisture or oxygen penetrates into the light emitting diode, various defects such as dark spots and pixel shrinkage and reduced lifespan may occur due to the oxidation of the metal electrode, the deterioration in the organic emission layer, or the like. The pixel shrinkage defect refers to a defect in which the edge of the pixel turns black due to the oxidation or deterioration in the interface between the metal electrode and the organic emission layer due to the penetration of moisture, and when the pixel shrinkage defect is left for a long period of time, it may worsen into the dark spot defect where the entire pixel area becomes black, thereby seriously affecting the reliability of the display device.

Accordingly, the display device 100 according to the exemplary embodiment of the present disclosure includes the protective layer GET surrounding the side surface of the encapsulation layer. In this way, by disposing the protective layer GET to surround each side portion of the plurality of plate patterns PP, it is possible to delay the penetration of moisture or oxygen from the lateral direction of the plurality of plate patterns PP. Accordingly, the path through which the moisture or oxygen penetrates into the light emitting diode LD may be blocked. Accordingly, in the display device 100 according to the exemplary embodiment of the present disclosure, various defects due to the penetration of moisture and oxygen may be prevented and the reliability may be improved.

In addition, in the display device 100 according to the exemplary embodiment of the present disclosure, the protective layer GET further includes the moisture-absorbing material, so the moisture or oxygen that may penetrate from the side surface may be absorbed by the protective layer GET. Accordingly, the moisture or oxygen that may penetrate from the side surface may be more effectively prevented from penetrating into the light emitting diode LD.

In the display device 100 according to the exemplary embodiment of the present disclosure, the protective layer GET may be disposed to cover the ends of the first inorganic encapsulation layer PAS1 and the second inorganic encapsulation layer PAS2. Accordingly, the ends of the first inorganic encapsulation layer PAS1 and the second inorganic encapsulation layer PAS2 may be completely sealed, and the penetration of moisture or oxygen from the side surface may be further delayed.

In the display device 100 according to the exemplary embodiment of the present disclosure, the protective layer GET may be formed of a stretchable organic material. Accordingly, even if the shape of the display device 100 is freely changed, the display device 100 may be maintained without being damaged. Additionally, even in situations where the shape of the display device 100 is deformed, the moisture or oxygen may be blocked from penetrating into the light emitting diode LD.

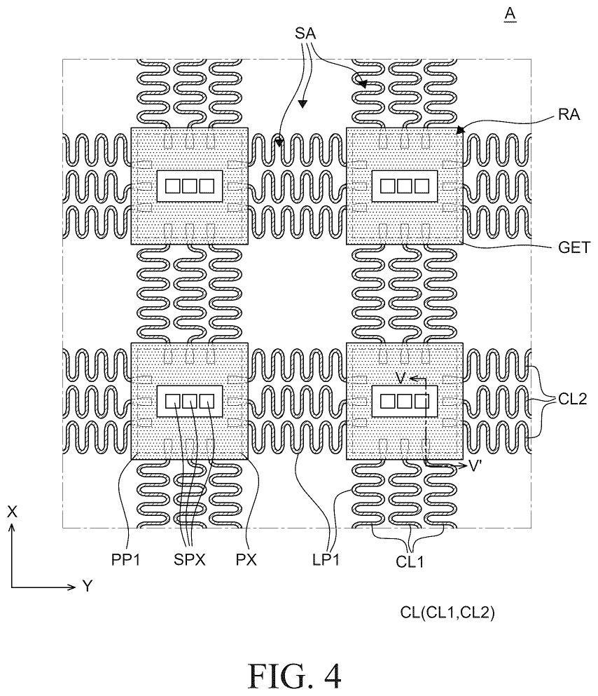

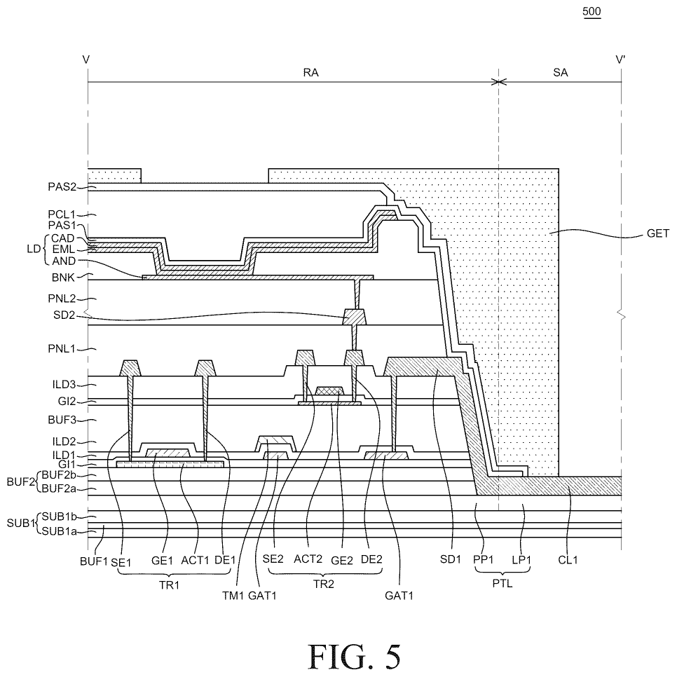

FIG. 4 is an enlarged plan view of an active area of a display device according to another exemplary embodiment of the present disclosure. FIG. 5 is a cross-sectional view taken along line V-V′ of FIG. 4. A display device 500 of FIGS. 4 and 5 is different from the display device 100 of FIGS. 1 to 3 in the configuration of the protective layer GET, and other components are substantially the same, and therefore, redundant descriptions thereof will be omitted.

Referring to FIGS. 4 and 5, in the display device 500 according to another exemplary embodiment of the present disclosure, the protective layer GET may be disposed to overlap a portion of the anode AND of each of the plurality of light emitting diodes LD. For example, the protective layer GET may be disposed on the bank BNK to overlap the bank BNK covering the end of the anode AND. In this case, the top surface of the protective layer GET may be disposed higher than the top surface of the encapsulation layer.

In addition, the protective layer GET may overlap some of the plurality of transistors TR1 and TR2. Alternatively, the protective layer GET may overlap at least portion of at least one of the plurality of transistors TR1 and TR2. FIG. 5 illustrates that the protective layer GET overlaps the second transistor TR2, but this is only an example and is not limited thereto.

In the display device 500 according to another exemplary embodiment of the present disclosure, the protective layer GET may include openings corresponding to the plurality of emission areas on the bank. Accordingly, the protective layer GET may be disposed so as not to overlap the emission area. For example, in the cross section, a width of the opening may be greater than the width of the emission area, but is not limited thereto. In this case, the emission area may refer to the area between the adjacent banks BNK disposed on the first planarization layer PNL1. For example, the emission area may be the area where the bank BNK is not disposed.

Accordingly, in the display device 500 according to another exemplary embodiment of the present disclosure, the protective layer GET may be disposed to surround each side portion of the plurality of plate patterns PP, so the penetration of moisture or oxygen from the side surfaces of the plurality of plate patterns PP may be blocked or delayed. In addition, by disposing the protective layer GET to overlap a portion of the anode AND, it is possible to block or delay the penetration of moisture or oxygen not only through the side surfaces but also through the top surface of each of the plurality of plate patterns PP.

In the display device 500 according to another exemplary embodiment of the present disclosure, the protective layer GET may not be disposed in the area overlapping the emission area on the encapsulation layer. Accordingly, when the light emitted from the emission area is emitted to the outside, the interference caused by the protective layer GET, which may be formed of an organic material, may be prevented. Accordingly, the luminous efficiency may be improved in the display device 500 according to another exemplary embodiment of the present disclosure.

In addition, in the display device 500 according to another exemplary embodiment of the present disclosure, it is possible to completely seal the ends of the first inorganic encapsulation layer PAS1 and the second inorganic encapsulation layer PAS2, and further delay the penetration of moisture or oxygen.

In addition, in the display device 500 according to another exemplary embodiment of the present disclosure, it is possible to block the moisture or oxygen from penetrating into the light emitting diode LD even in the situation where the shape of the display device 500 is deformed.

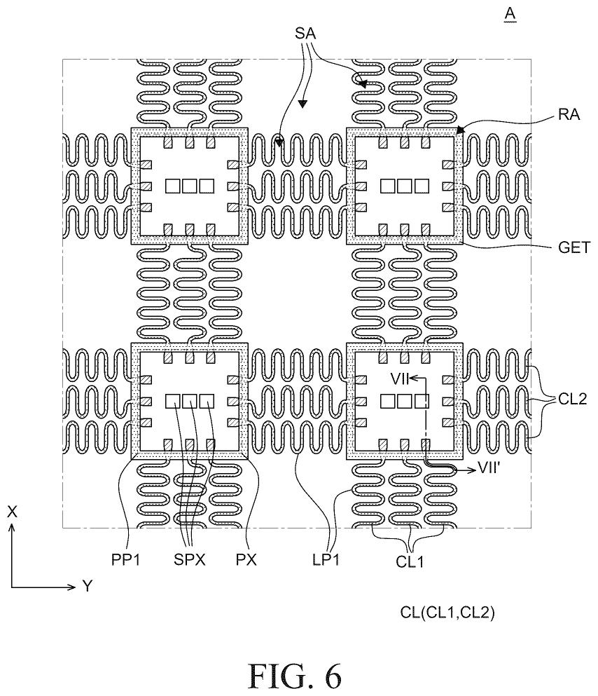

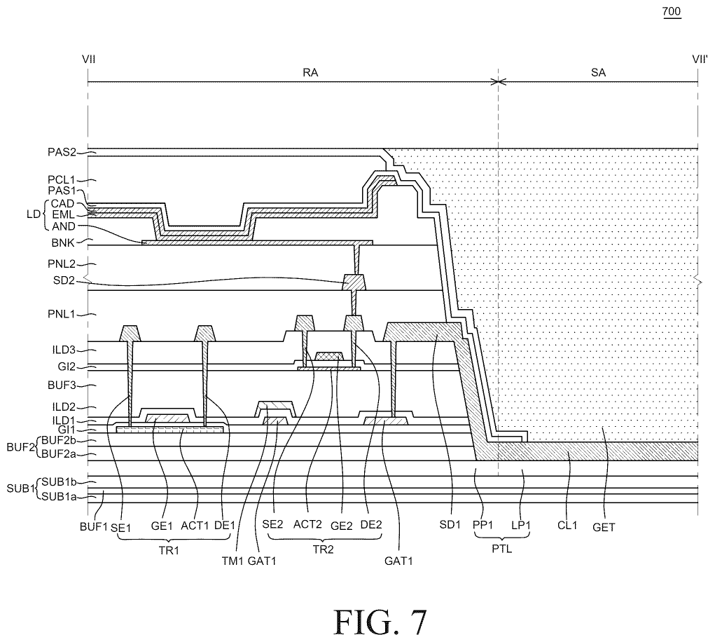

FIG. 6 is an enlarged plan view of the active area of the display device according to still another exemplary embodiment of the present disclosure. FIG. 7 is a cross-sectional view taken along line VII-VII′ of FIG. 6. A display device 700 of FIGS. 6 and 7 is different from the display device 100 of FIGS. 1 to 3 in the configuration of the protective layer GET, and other components are substantially the same, and therefore, redundant descriptions thereof will be omitted.

Referring to FIGS. 6 and 7, in the display device 700 according to still another exemplary embodiment of the present disclosure, the protective layer GET may be disposed to surround the side surface of the encapsulation layer. In addition, the protective layer GET may also be disposed on the plurality of connection lines CL. For example, the protective layer GET may be disposed to cover the entire top surface of each of the plurality of connection lines CL connecting the adjacent plate patterns PP among the plurality of plate patterns PP. In addition, the protective layer GET surrounding the side surface of the encapsulation layer and the protective layer GET disposed on the plurality of connection lines CL may be connected to each other. For example, the protective layer GET surrounding the side surface of the encapsulation layer and the protective layer GET disposed on the plurality of connection lines CL may be formed of the same material. In this case, these protective layers GET may be integrated. Alternatively, the protective layer GET surrounding the side surface of the encapsulation layer and the protective layer GET disposed on the plurality of connection lines CL may be formed of different materials. In addition, the top surface of the protective layer GET disposed on the plurality of connection lines CL may be positioned on the same plane as the top surface of the encapsulation layer that is not covered by the protective layer GET. For example, the top surface of the protective layer GET disposed on the first connection line CL1 may be positioned on the same plane as the top surface of a portion of the second inorganic encapsulation layer PAS2 that is overlapping with the first organic encapsulation layer PCL1 and not covered by the protective layer GET.

In addition, the protective layer GET and the plurality of connection lines CL may have the same shape and width on a plane. In addition, the protective layer GET may be disposed to completely overlap the plurality of connection lines CL.

Accordingly, the display device 700 according to still another exemplary embodiment of the present disclosure may block the path through which the moisture or oxygen penetrates from the lateral direction of each of the plurality of plate patterns PP into the light emitting diode LD.

At the same time, it is possible to block the contact of moisture or oxygen with the connection line CL. Therefore, it is possible to prevent the connection line CL from being corroded due to the moisture or oxygen. In addition, it is possible to prevent or improve various defects that may occur as the connection line CL corrodes. As a result, it is possible to improve the reliability of the connection line CL.

In addition, the display device 700 according to still another exemplary embodiment of the present disclosure may completely seal the ends of the first inorganic encapsulation layer PAS1 and the ends of the second inorganic encapsulation layer PAS2. Accordingly, it is possible to more delay the penetration of moisture or oxygen from the side surface.

In addition, in the display device 700 according to still another exemplary embodiment of the present disclosure, it is possible to block the moisture or oxygen from penetrating into the plurality of light emitting diodes LD or the plurality of connection lines CL while the display device is not damaged even in the situation where the shape of the display device 700 is deformed.

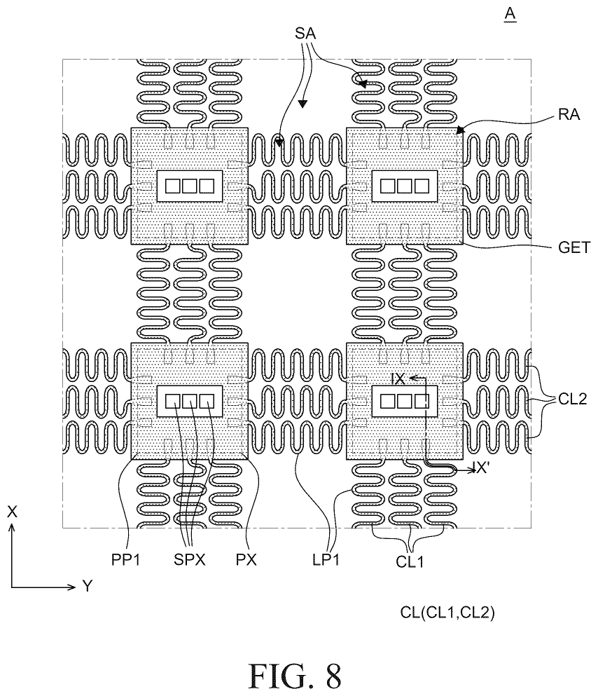

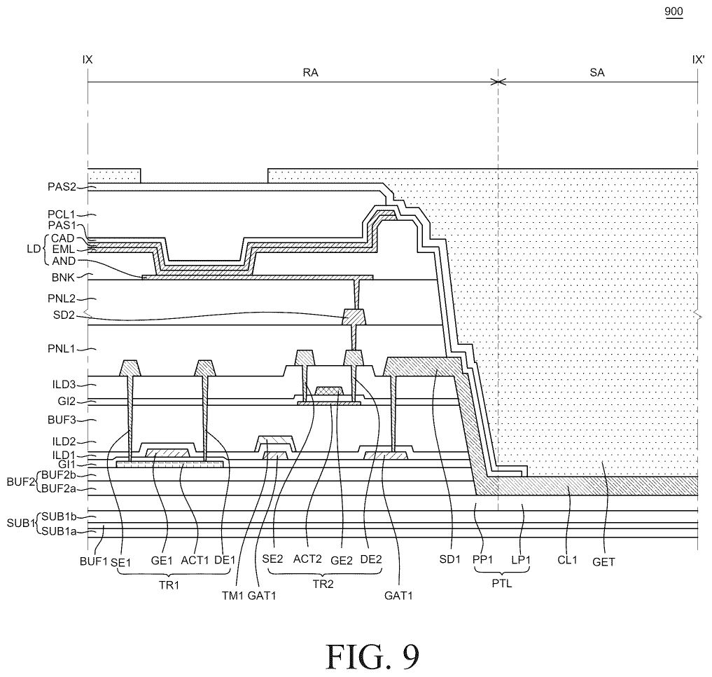

FIG. 8 is an enlarged plan view of the active area of the display device according to still another exemplary embodiment of the present disclosure. FIG. 9 is a cross-sectional view taken along line IX-IX′ of FIG. 8. A display device 900 of FIGS. 8 and 9 is different from the display device 500 of FIGS. 4 and 5 in the configuration of the protective layer GET, and other components are substantially the same, and therefore, redundant descriptions thereof will be omitted.

Referring to FIGS. 8 and 9, in the display device 900 according to still another exemplary embodiment of the present disclosure, the protective layer GET may be disposed on the encapsulation layer to overlap a portion of the anode AND of each of the plurality of light emitting diodes LD. In addition, the protective layer GET may also be disposed on the plurality of connection lines CL. For example, the protective layer GET may be disposed to cover the entire top surface of each of the plurality of connection lines CL connecting the adjacent plate patterns PP among the plurality of soft plate patterns PP to each other. In this case, the top surface of the protective layer GET disposed on the plurality of connection lines CL may be higher than the top surface of the encapsulation layer on the plurality of plate pattern PP. In addition, the top surface of the protective layer disposed on each of the plurality of plate patterns PP and the top surface of the protective layer GET disposed on the plurality of connection lines CL may be positioned on the same plane. The protective layer GET on the plurality of plate patterns PP and the protective layer GET on the plurality of connection lines CL may be formed of the same material. In this case, these protective layers GET may be integrated. Alternatively, the protective layer GET on the plurality of plate patterns PP and the protective layer GET on the plurality of connection lines CL may be formed of different materials.

In addition, the protective layer GET and the plurality of connection lines CL may have the same shape and width on a plane. In addition, the protective layer GET may be disposed to completely overlap the plurality of connection lines CL.

Accordingly, the display device 900 according to still another exemplary embodiment of the present disclosure may block the path through which the moisture or oxygen penetrates from the lateral direction of each of the plurality of plate patterns PP into the light emitting diode LD. In addition, the display device 900 according to still another exemplary embodiment of the present disclosure may delay or block the moisture or oxygen from penetrating from the top surface of the encapsulation layer into each of the plurality of light emitting diodes LD.

In addition, the display device 900 according to still another exemplary embodiment of the present disclosure may delay or block the moisture or oxygen from penetrating into each of the plurality of connection lines CL. Accordingly, the corrosion that may occur when the moisture or oxygen penetration is in contact with each of the plurality of connection lines CL may be prevented. Accordingly, various defects that may occur in the plurality of connection lines CL may be prevented or improved.

In addition, the display device 900 according to still another exemplary embodiment of the present disclosure may completely seal the ends of the first inorganic encapsulation layer PAS1 and the ends of the second inorganic encapsulation layer PAS2. Accordingly, it is possible to more delay the penetration of moisture or oxygen from the side surface.

In addition, in the display device 900 according to still another exemplary embodiment of the present disclosure, it is possible to block the moisture or oxygen from penetrating into the plurality of light emitting diodes LD or the plurality of connection lines CL while the display device is not damaged even in the situations where the shape of the display device 900 is deformed.

The exemplary embodiments of the present disclosure can also be described as follows:

According to the exemplary embodiments of the present disclosure, a display device comprises: a substrate; light emitting elements disposed over the substrate; an encapsulation layer covering the light emitting elements; and a protective layer disposed to surround side surfaces of the encapsulation layer.

According to the exemplary embodiments of the present disclosure, the protective layer is disposed to surround the light emitting elements.

According to the exemplary embodiments of the present disclosure, the display device further comprises insulating layers between the light emitting elements and the substrate, the encapsulation layer extends along side surfaces of insulating layers.

According to the exemplary embodiments of the present disclosure, the protective layer includes moisture-absorbing materials.

According to the exemplary embodiments of the present disclosure, the protective layer is formed of a stretchable organic material.

According to the exemplary embodiments of the present disclosure, the display device further comprises a pattern layer disposed on the substrate, the pattern layer including a plurality of plate patterns disposed in rigid areas and a plurality of line patterns disposed in soft areas, wherein the plurality of line patterns connecting the plate patterns adjacent to each other, and the light emitting elements are disposed over the plurality of line patterns.

According to the exemplary embodiments of the present disclosure, the encapsulation layer includes a first inorganic encapsulation layer, an organic encapsulation layer, and a second inorganic encapsulation layer sequentially stacked, and each of the first inorganic encapsulation layer and the second inorganic encapsulation layer extends from the rigid area to the soft area.

According to the exemplary embodiments of the present disclosure, the display device further comprises insulating layers between the light emitting elements and the plurality of plate patterns, the first inorganic encapsulation layer and the second inorganic encapsulation layer extend along side surfaces of insulating layers and are in contact with each other.

According to the exemplary embodiments of the present disclosure, the display device further comprises a plurality of connection lines disposed on the plurality of line patterns, the plurality of connection lines electrically connect pads on the plurality of plate patterns to each other, and ends of the first inorganic encapsulation layer and ends of the second inorganic encapsulation layer are disposed on the plurality of connection lines.

According to the exemplary embodiments of the present disclosure, the protective layer includes a first protective layer disposed in the rigid area and surrounding side surfaces of the encapsulation layer, and a second protective layer covering the plurality of connection lines and the ends of the first inorganic encapsulation layer and the ends of the second inorganic encapsulation layer.

According to the exemplary embodiments of the present disclosure, the first protective layer and the second protective layer are formed of a same material.

According to the exemplary embodiments of the present disclosure, the first protective layer and the second protective layer are formed of different materials.

According to the exemplary embodiments of the present disclosure, a top surface of the first protective layer and a top surface of the second protective layer are positioned on a same plane.

According to the exemplary embodiments of the present disclosure, a top surface of the protective layer and a top surface of the encapsulation layer are positioned on a same plane.

According to the exemplary embodiments of the present disclosure, the first protective layer is disposed to overlap with a portion of an anode electrode of the light emitting element.

According to the exemplary embodiments of the present disclosure, a top surface of the protective layer is disposed to be higher than a top surface of the encapsulation layer.

According to the exemplary embodiments of the present disclosure, the second protective layer and the plurality of connection lines have same shape and width on a plane.

According to the exemplary embodiments of the present disclosure, the plurality of plate patterns are disposed in the form of islands spaced apart from each other.

According to the exemplary embodiments of the present disclosure, the plurality of line patterns have a curved shape.

According to the exemplary embodiments of the present disclosure, the display device further comprises a bank covering a portion of an anode electrode of the light emitting element, the protective layer includes an opening corresponding to another portion of the anode electrode exposed from the bank.

According to the exemplary embodiments of the present disclosure, the bank is configured to have a stepped structure.

According to the exemplary embodiments of the present disclosure, the encapsulation layer extends along the side surface of the bank with the stepped structure.

According to the exemplary embodiments of the present disclosure, a width of the opening is greater than a width of the another portion of the anode electrode exposed from the bank.

According to the exemplary embodiments of the present disclosure, the substrate includes a first substrate and a second substrate, and a first buffer layer is disposed between the first substrate and the second substrate.

According to the exemplary embodiments of the present disclosure, the display device further comprises a second buffer layer disposed on the plurality of plate patterns, and the plurality of plate patterns are disposed on the second substrate.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a stretchable substrate;
a plurality of plate patterns spaced apart from each other on the substrate;
a plurality of light emitting diodes disposed on the plurality of plate patterns;
a plurality of connection lines disposed between the plurality of plate patterns and being stretchable;
an encapsulation layer covering the plurality of light emitting diodes; and
a protective layer surrounding a side surface of the encapsulation layer.

2. The display device of claim 1, wherein a top surface of the encapsulation layer and a top surface of the protective layer are positioned on the same plane.

3. The display device of claim 1, wherein the encapsulation layer further includes:
a first inorganic encapsulation layer;
an organic encapsulation layer disposed on the first inorganic encapsulation layer; and
a second inorganic encapsulation layer disposed on the first inorganic encapsulation layer and the organic encapsulation layer, and
the first inorganic encapsulation layer and the second inorganic encapsulation layer are in contact with each other in an outer area of the plurality of plate patterns.

4. The display device of claim 3, wherein the protective layer covers ends of the first inorganic encapsulation layer and the second inorganic encapsulation layer.

5. The display device of claim 1, further comprising a bank disposed to cover ends of anodes of the plurality of light emitting diodes,
wherein the protective layer is disposed to overlap the bank on the plurality of plate patterns.

6. The display device of claim 5, wherein the protective layer overlaps the anodes of the plurality of light emitting diodes.

7. The display device of claim 5, further comprising a plurality of transistors disposed on the plurality of plate patterns,
wherein the protective layer overlaps some of the plurality of transistors.

8. The display device of claim 5, wherein a top surface of the protective layer is disposed higher than a top surface of the encapsulation layer.

9. The display device of claim 5, wherein the protective layer includes openings corresponding to a plurality of emission areas on the bank.

10. The display device of claim 1, wherein the protective layer is disposed on the plurality of connection lines.

11. The display device of claim 10, wherein the protective layer and the plurality of connection lines have the same shape and width on a plane.

12. The display device of claim 10, wherein the protective layer is disposed to completely overlap the plurality of connection lines.

13. The display device of claim 1, wherein the protective layer is formed of a stretchable organic material.

14. The display device of claim 1, wherein the protective layer includes a moisture-absorbing material.
